(19) United States
(12) Patent Application Publication
(10) Pub. No.: US 2010/0103389 A1
(43) Pub. Date: Apr. 29, 2010

(54) Multi-MEMS Single Package MEMS Device

(76) Inventors: Kenneth Brian McVea, Allen, TX (US); Bryce Daniel Sawyers, Allen, TX (US)

Correspondence Address: TEXAS INSTRUMENTS INCORPORATED, P O BOX 655474, M/S 3999, DALLAS, TX, 75265, US

(21) Appl. No.: 12/260,002

(22) Filed: Oct. 28, 2008

(51) Int. Cl. G03B 21/28; H01L 23/02; H01L 23/34

(52) U.S. Cl. 353/99; 257/723; 257/680; 257/E23.18; 257/E23.002

(57) ABSTRACT

A system and method for packaging multiple MEMS devices is disclosed. A preferred embodiment comprises two or more MEMS devices, such as DMD devices, packaged together into a single package. The MEMS devices can be either on a single substrate or else on multiple substrates, and may be aligned together or not aligned together depending upon the desired orientation of the MEMS devices.

### TECHNICAL FIELD

The present invention relates generally to a system and method for packaging microelectromechanical system devices, and more particularly to packaging digital micromirror devices.

### BACKGROUND

FIG. 1 illustrates a packaged microelectromechanical system (MEMS) device as generally known in the prior art. Once a MEMS device 101 has been formed through standard semiconductor processes, the MEMS device 101 is typically placed into a package 103 in order to protect it from environmental damage during the life and operation of the MEMS device 101. This package 103 contains all of the input and output characteristics required to operate the MEMS device 101, and, if the MEMS device comprises a spatial light modulator, typically includes a light transmissive surface in order to allow light to impinge upon the MEMS device 101.

One such MEMS device 101 is a digital micromirror device (DMD). DMDs are used in DLP® technology as optical switches or transmitters for television (TV) and projection systems. DMDs are optical semiconductor devices having an array of thousands or up to millions of micromirrors that are switched on or off at varying frequencies, forming a digital image. DMDs are extremely precise light switches that are capable of modulating light. Digital video or graphics are reproduced by the DMDs and projected onto a screen. Some projection systems may comprise a single DMD, whereas other projection systems may include three DMDs, as examples. Projection systems that utilize DMDs have a high fidelity and improved picture quality.

### SUMMARY OF THE INVENTION

These and other problems are generally solved or circumvented, and technical advantages are generally achieved, by preferred embodiments of the present invention that allow for multiple MEMS devices to be packaged into a single package.

One preferred embodiment of the present invention comprises a microelectromechanical (MEMS) comprising a single package. A plurality of MEMS devices are located within the single package and the plurality of MEMS devices are separated from each other by at least one area that contains no MEMS devices.

Another preferred embodiment comprises a first array of micromirrors and a second array of micromirrors that are spatially separated from the first array of micromirrors. A package surrounds the first array of mircromirrors and the second array of micromirrors. The package also comprises a light transmissive surface to allow light to impinge the first array of micromirrors and the second array of micromirrors.

Yet another preferred embodiment comprises a projection system comprising a light source and a first reflector positioned to direct light from the light source to a single package, the single package comprising a light-transmissive surface. A plurality of micromirror arrays are located within the single package, each of the plurality of micromirror arrays being spatially separated from adjoining micromirror arrays. A second reflector is positioned to direct light reflected from the plurality of micromirror arrays away from the light source.

By using these embodiments the costs of multiple packages can be reduced. Further, the manufacturing complications such as transportation, testing, and alignment that are a part of multiple package systems can be reduced, increasing the overall efficiency of the manufacturing process.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a microelectromechanical device packaged in the prior art;

FIGS. 2A-2B illustrate a plan view and a cross-sectional view of multi-array single package in accordance with an embodiment of the present invention;

FIG. 3 illustrates an array of multiple MEMS devices on a single substrate packaged together in accordance with an embodiment of the present invention;

FIG. 4A-4B illustrate various arrangements of multiple MEMS devices in accordance with an embodiment of the present invention;

FIG. 5A-5B illustrate four MEMS devices and two MEMS devices packaged together in accordance with an embodiment of the present invention; and

FIGS. 6A-6B illustrate two embodiments of the multi-array single package in conjunction with a projection system for projecting an image in accordance with an embodiment of the present invention.

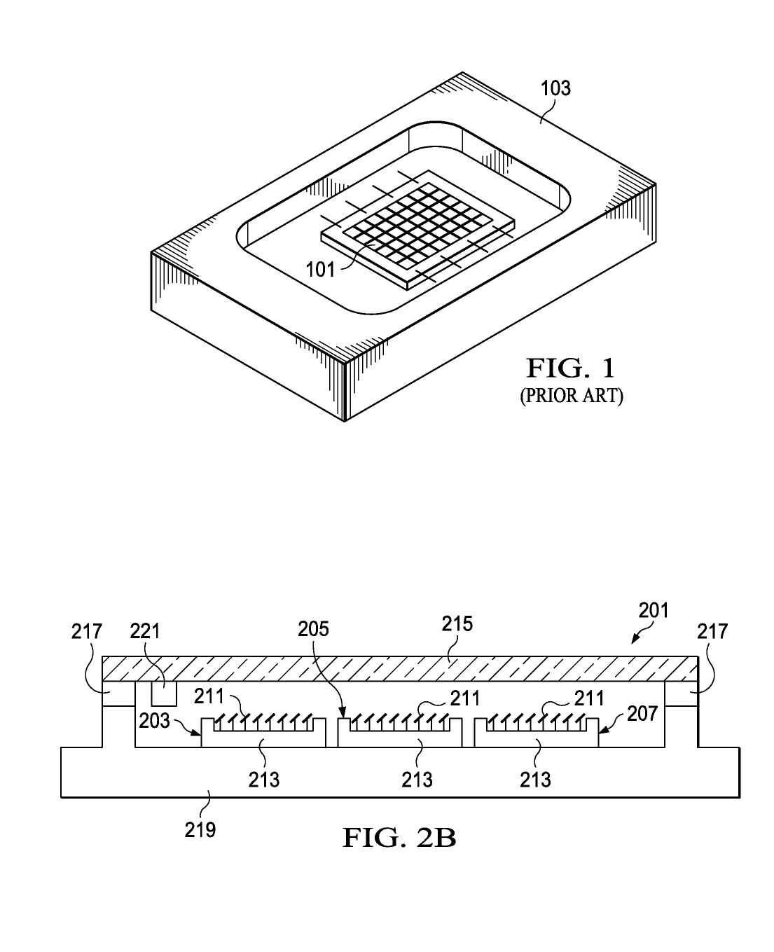

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to microelectromechanical (MEMS) devices that comprise digital micromirror devices (DMDs) in a projection system. The invention may also be applied, however, to other MEMS devices, and also to other applications, such as telecommunication devices.

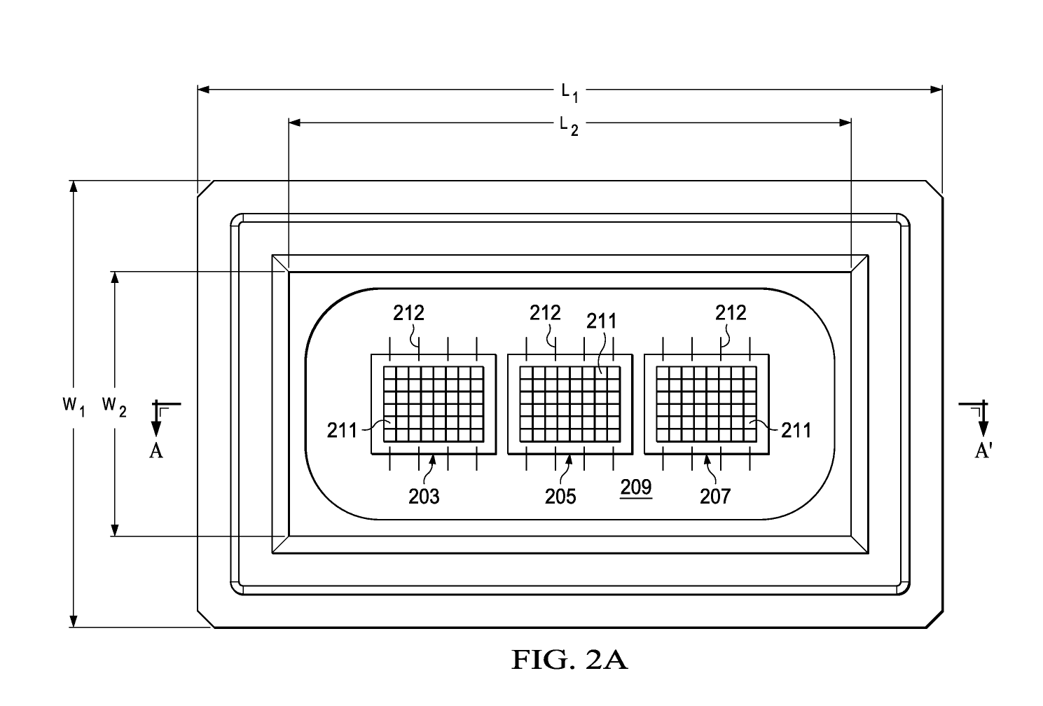

FIGS. 2A-2B show a plan view and a cross-sectional view along line A-A′, respectively, of a package 201 with a first MEMS device 203, a second MEMS device 205, and a third MEMS device 207 located within a cavity 209 of the package 201. The package 201 preferably comprises a Type A package comprising a substrate 219 along with a hermetic window 215 (described further below) to cover and protect the cavity 209 formed by the package 201. The substrate 219 preferably comprises a ceramic header along with a heat sink to dissipate heat. The package 201 also preferably comprises a getter material 221 located within the cavity 209 in order to protect elements within the cavity 209 after the hermetic window 215 has been sealed to the substrate 219.

The package 201 preferably comprises a first length l₁ of between about 1.06 inches and about 4.06 inches, with a preferred first length l₁ of about 2.6 inches, and a first width w₁ of between about 1 inch and about 2.5 inches, with a preferred first width w₁ of about 1.25 inches. The cavity 209 preferably has a second length l₂ of between about 0.75 inches and about 3.5 inches, with a preferred second length l₂ of about 2.2 inches, and a second width w₂ of between about 0.5 inches and about 2 inches, with a preferred second width w₂ of about 0.9 inches.

As one of ordinary skill in the art will recognize, the Type A package described above is merely one type of suitable package that may be used in embodiments of the present invention, and the above description is meant to be merely illustrative and not limiting. Any type of package, such as Type A packages, Type X packages, wafer level packages (WLP), or the like may alternatively be used. These types of packages 201 are all intended to be fully included within the scope of the present invention.

Attached within the cavity 209 of package 201 are the first MEMS device 203, the second MEMS device 205, and the third MEMS device 207, preferably separated from each other by an area that has no other MEMS devices. The first MEMS device 203, the second MEMS device 205, and the third MEMS device 207 are preferably digital micromirror devices (DMDs), each preferably comprising an array of micromirrors 211. However, other devices, such as photonic devices, optical devices (e.g., including reflective, refractive and diffractive type devices), microoptoelectromechanical system (e.g. MOEMS) devices, or the like could alternatively be used.

The micromirrors 211 are preferably formed either on or within one or more MEMS substrates 213 (unseen in FIG. 2A but illustrated in FIG. 2B). The MEMS substrates 213 preferably comprise bulk silicon or an active layer of a silicon-on-insulator (SOI) substrate. Other MEMS substrates 213 that may be used include multi-layered substrates, gradient substrates, or hybrid orientation substrates. While only a small number of micromirrors 211 are shown in FIG. 2A for clarity, it should be understood that the actual number of micromirrors 211 is dependent upon the design, and could well exceed over a million distinct micromirrors 211. For example, the preferred arrays that may be used for this invention are completely scalable and could comprise enough micromirrors 211 to meet resolutions such as 640×480, 720×480, 1280×720, 1920×1080, or other suitable resolutions.

Electrical control circuitry (not shown) is preferably fabricated on or within the surface of the MEMS substrates 213 or the package 201 using any suitable integrated circuit process flow. This circuitry preferably includes a MEMSory cell (not shown) associated with, and typically underlying, each micromirror 211 of the first MEMS device 203, the second MEMS device 205, and the third MEMS device 207. The circuitry also preferably comprises digital logic circuits to control the transfer of data to the underlying MEMSory cells. Voltage driver circuits to drive bias and reset signals to the micromirrors 211 are preferably fabricated on the MEMS substrates 213, package 201, or may alternatively be external to the micromirrors 211.

The micromirrors 211 are preferably formed so as to be rotatable around a torsional hinge connected to the MEMS substrates 213. In operation the electrical control circuitry applies a bias to generate an electrical field in the vicinity of a desired micromirror 211, which causes the micromirror 211 to rotate to a desired angle. Light impacting the array of micromirrors 211 is preferably modulated by reflecting from a number of micromirrors 211 rotated to one angle, while undesired light is reflected along a separate angle by micromirrors 211 rotated to a second angle. The advantage of using three MEMs devices is that each device can illuminate one of the primary colors red, green, and blue (or two complementary colors), thereby providing increased brightness relative to a single packaged device.

The first MEMS device 203, the second MEMS device 205, and the third MEMS device 207 are preferably electrically connected to the package 201 by bond wires 212. The bond wires 212 are used to route electrical signals from outside of the package 201 to the first MEMS device 203, the second MEMS device 205, and the third MEMS device 207. Other types of connections, however, such as through silicon vias and solder bumps, may alternatively be used.

In one preferred embodiment the first MEMS device 203, the second MEMS device 205, and the third MEMS device 207 are preferably aligned in a landscape configuration, wherein the first MEMS device 203, the second MEMS device 205, and the third MEMS device 207 are aligned with each other to form a row of aligned arrays. In this configuration bond wires 212 for each of the first MEMS device 203, the second MEMS device 205, and the third MEMS device 207 are preferably all located to extend between their respective device and the package 201 without extending towards the other MEMS devices.

Once the first MEMS device 203, the second MEMS device 205, and the third MEMS device 207 have been located within the cavity 209 of the package 201, the hermetic window 215 is preferably located relative to the rest of the package 201 so as to enclose the first MEMS device 203, the second MEMS device 205, and the third MEMS device 207 within the cavity 209. The cover 215 may be completely opaque or completely transparent, depending upon the particular MEMS device 215 that is being enclosed. However, for a DMD device the cover 215 is preferably opaque while additionally having a transparent window 219 to selectively allow for the passage of light into and out of the cavity 209. This usage of a window 219 assures that light from outside the cavity 209 is limited to a more specific or precise area of the first MEMS device 203, the second MEMS device 205, and the third MEMS device 207. The cover 215 preferably has a thickness of between about 0.7 mm and about 3 mm, with a preferred thickness of about 1.1 mm.

By placing multiple MEMS devices into a single package 201, the costs associated with multiple packages (a single package for each MEMS device) can be reduced. Further, manufacturing complications associated with transportation, alignment, and testing may be reduced to make the overall manufacturing process more efficient and less costly.

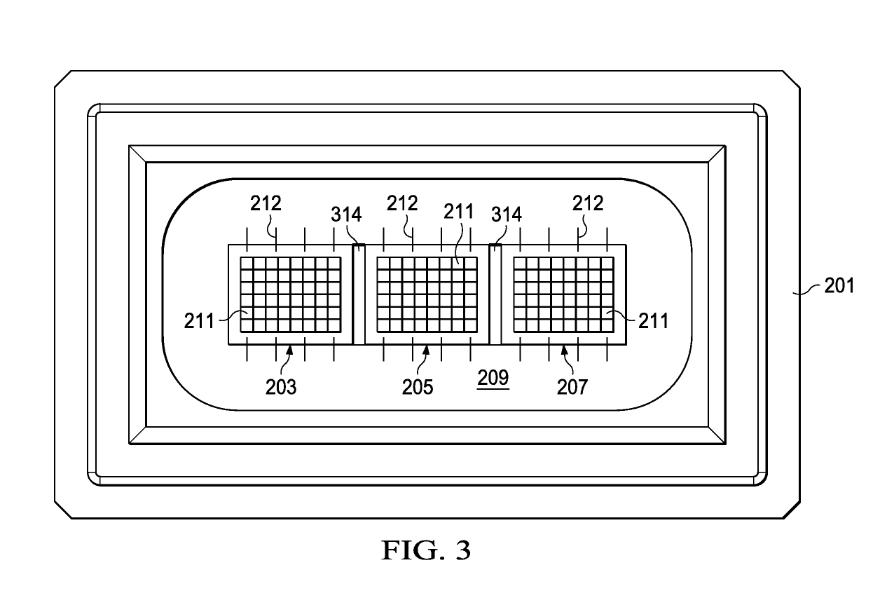

FIG. 3 illustrates another preferred embodiment in which the first MEMS device 203, the second MEMS device 205, and the third MEMS device 207 are all formed and aligned on a single wafer. In this embodiment the first MEMS device 203, the second MEMS device 205, and the third MEMS device 207 are preferably formed together on a single wafer and are then singulated from the wafer as a single piece. This process keeps the devices physically interconnected and aligned through the single MEMS substrate 214 wafer on a single MEMS substrate 213, but the first MEMS device 203, the second MEMS device 205, and the third MEMS device 207 would still be separated by regions 314 in which there are no micromirrors 211 or active circuitry. This single MEMS substrate 213 with the aligned first MEMS device 203, second MEMS device 205, and third MEMS device 207, is then preferably placed into the package 201.

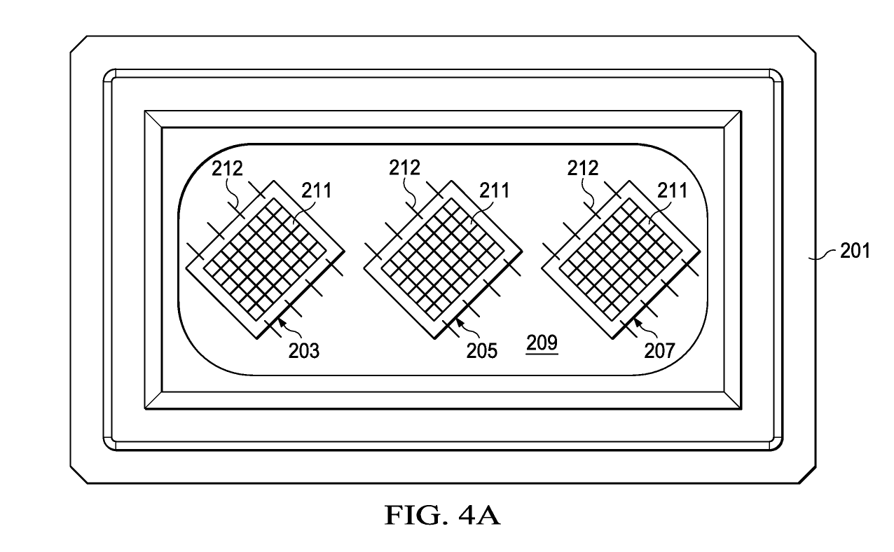

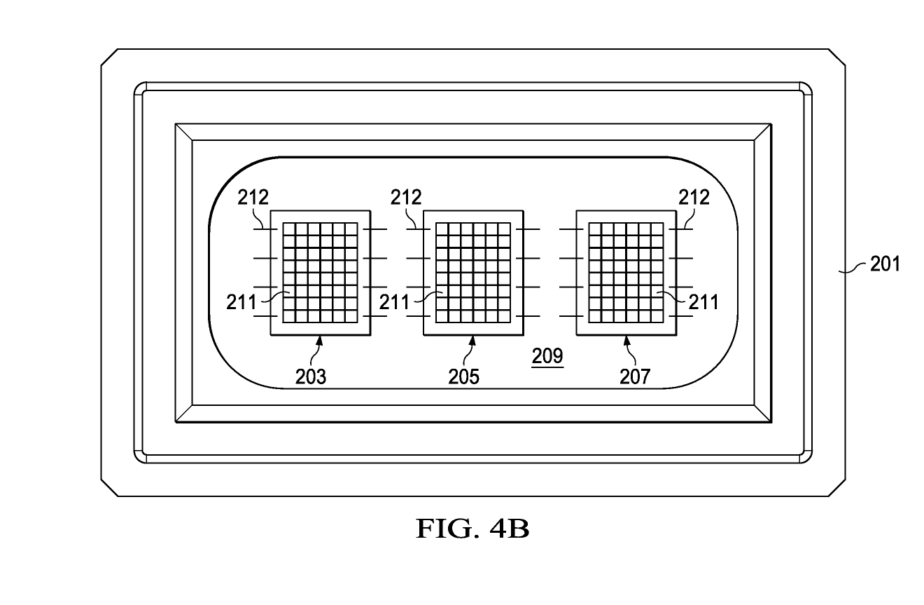

FIG. 4A illustrates another embodiment in which the first MEMS device 203, the second MEMS device 205, and the third MEMS device 207 are preferably aligned in a diamond configuration where the first MEMS device 203, the second MEMS device 205, and the third MEMS device 207 have sides that are not aligned along a straight line. In this embodiment, the first MEMS device 203, the second MEMS device 205, and the third MEMS device 207 are located at an angle that is not perpendicular to the edges of the package 201, for example a 45° angle. This embodiment is especially useful when the incident light would not impact the first MEMS device 203, the second MEMS device 205, and the third MEMS device 207 at close to right angles, but at more acute angles than the other embodiments.

FIG. 4B illustrates another embodiment in which the first MEMS device 203, the second MEMS device 205, and the third MEMS device 207 are arranged in a portrait configuration similar to the landscape configuration (described above with respect to FIG. 2A). In this embodiment, however, the first MEMS device 203, the second MEMS device 205, and the third MEMS device 207 are preferably separated from each other and are spaced farther apart from each other than in the landscape embodiment. Accordingly, with the extra spacing between the first MEMS device 203, the second MEMS device 205, and the third MEMS device 207, the bond wires 212 are preferably attached to the area between the first MEMS device 203, the second MEMS device 205, and the third MEMS device 207. This embodiment may be preferred depending upon the incoming angle of light to be modulated, such as when the package 201 is situated such that incoming light would strike the first MEMS device 203, the second MEMS device 205, and the third MEMS device 207 where the bond wires 212 would be located in the landscape configuration.

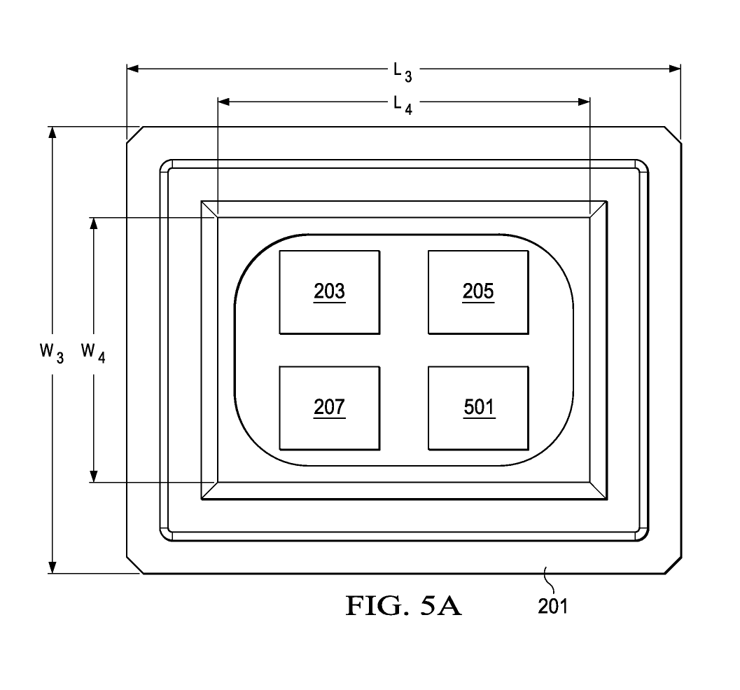

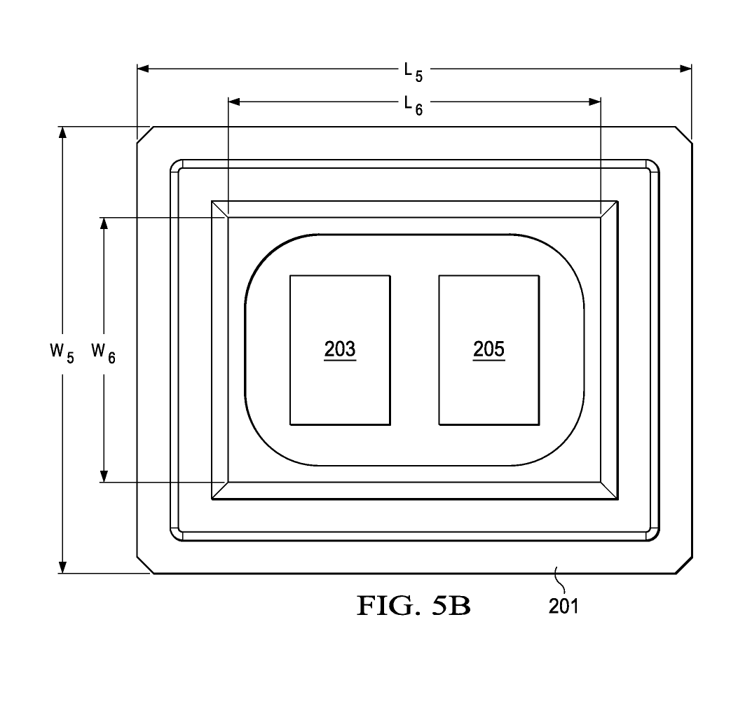

FIG. 5A illustrates yet another embodiment in which a fourth MEMS device 501 is included within the package 201 along with the first MEMS device 203, the second MEMS device 205, and the third MEMS device 207 and may be either singulated onto separate MEMS substrates 213 or else formed on a single MEMS substrate 213. In this embodiment the first MEMS device 203, the second MEMS device 205, the third MEMS device 207, and the fourth MEMS device 501 are preferably arranged in a square pattern within the package 201, although any suitable configuration (e.g., landscape, diamond, or portraint) may alternatively be used. This embodiment is preferably used when at least four different colors of light are to be modulated separately from each other, which allows for better modulation of the separate colors of light. This embodiment also alternatively allows only the first MEMS device 203, the second MEMS device 205, and the third MEMS device 207 to be operated, while the fourth MEMS device 501 may be retained as a spare device in case one of the other devices fail.

In this embodiment, because there is a fourth MEMS device 501 within the package 201, the preferred dimensions of the package 201 would preferably change as well. In this embodiment the package 201 preferably comprises a third length l₃ of between about 1 inch and about 3.1 inches, with a preferred third length l₃ of about 2.1 inches, and a third width w₃ of between about 2.75 inches and about 3 inches, with a preferred third width w₃ of about 1.75 inches. The cavity 209 preferably has a fourth length l₄ of between about 0.5 inches and about 2.5 inches, with a preferred fourth length l₄ of about 1.7 inches, and a fourth width w₄ of between about 0.5 inches and about 2.8 inches, with a preferred fourth width w₄ of about 1.4 inches.

FIG. 5B illustrates yet another embodiment in which only the first MEMS device 203 and the second MEMS device 205 are located within the package 201. These two devices may be either aligned or non-aligned, and may also be either singulated onto separate MEMS substrates 213 or formed on a single MEMS substrate 213. This embodiment is especially useful to further save costs and space by dedicating one of either the first MEMS device 203 or the second MEMS device 205 to green and the other to red and blue.

In this embodiment, as with the embodiment in which there is a fourth MEMS device 501 within the package 201 (described above with respect to FIG. 5A), the preferred dimensions of the package 201 in this embodiment would preferably change as well. In this embodiment the package 201 preferably comprises a fifth length l₅ of between about 1 inch and about 4 inches, with a preferred fifth length l₅ of about 2.1 inches, and a fifth width w₅ of between about 1.75 inches and about 2.1 inches, with a preferred fifth width W5 of about 1.75 inches. The cavity 209 preferably has a sixth length l₆ of between about 1.1 inches and about 2.7 inches, with a preferred sixth length l₆ of about 1.7 inches, and a sixth width w₆ of between about 1 inch and about 2 inches, with a preferred sixth width w of about 1.4 inches.

As one of ordinary skill in the art will recognize, the preferred embodiments described above with reference to FIGS. 2A-5B are merely illustrative and are not meant to limit the present invention to just these embodiments. Any number of a plurality of MEMS devices, arranged in any fashion within a single package may be used alternatively to those described above. All of these embodiments and alternatives are fully intended to be included within the scope of the present invention.

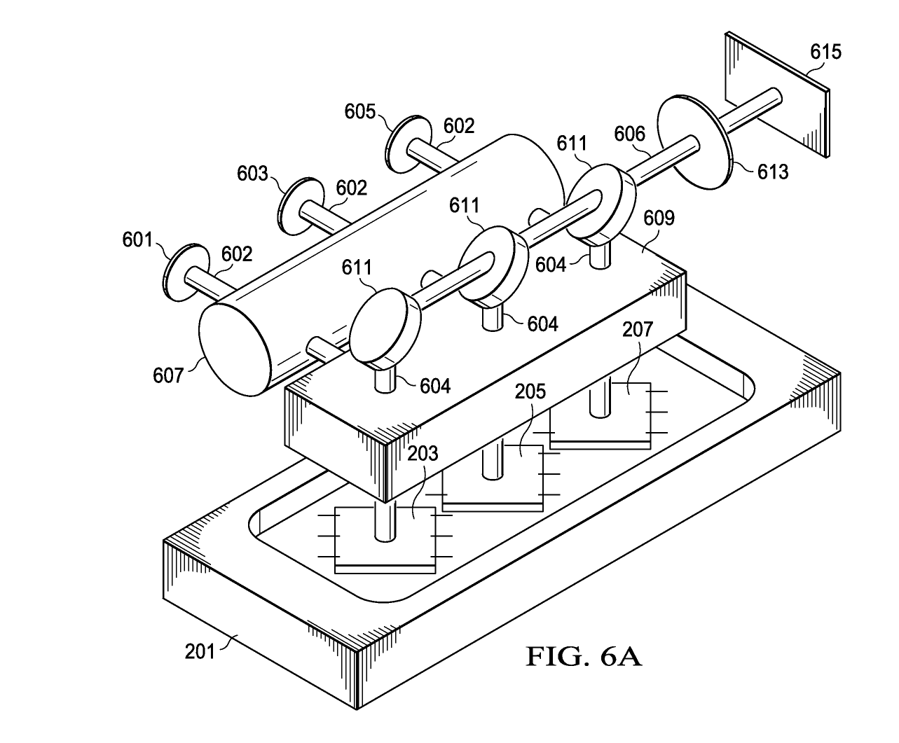

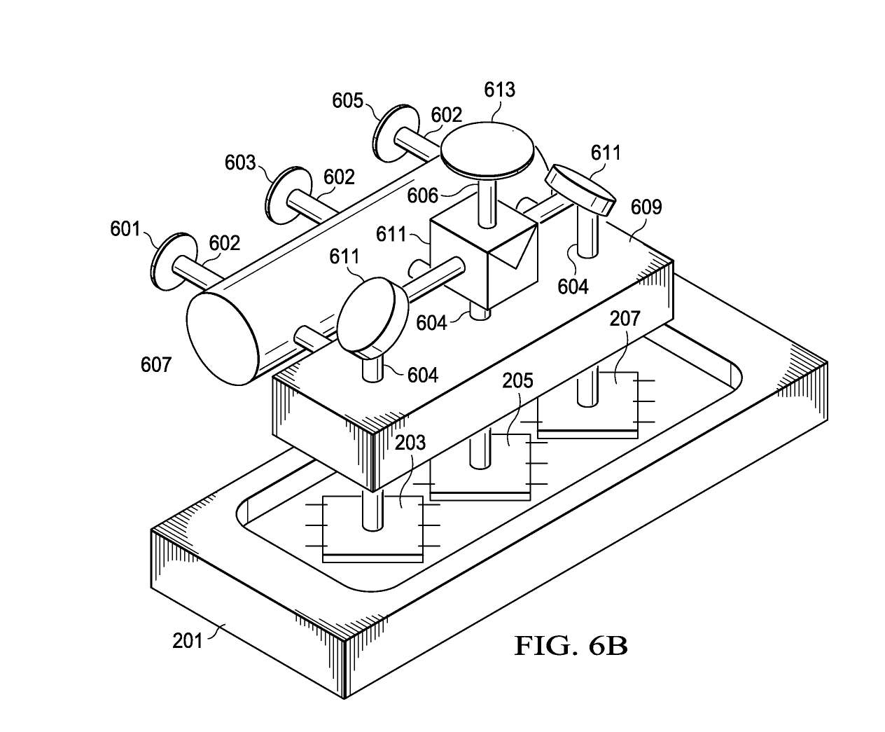

FIG. 6A illustrates a preferred embodiment of a display system that includes the package 201 described above with further optical components. In this embodiment there is a first light source 601, a second light source 603, and a third light source 605, each preferably emitting beams of light 602 that are preferably different colors such as red, blue, and green. The first light source 601, second light source 603, and third light source 605 are preferably lamps, but may also alternatively comprise LEDs, lasers, combinations of these, or the like. Additionally, if desired, filters (not shown) may be utilized in order to achieve the desired colors for each of the first light source 601, second light source 603, and third light source 605.

As one of skill in the art will recognize, the above embodiment of three separate light sources to form three separate colors of light is merely illustrative and is not meant to be limiting in any fashion. Any arrangement of light sources and other optics that may be utilized to form separate beams of differently colored lights may be utilized as well as the above description. For example, a single light source may be used in conjunction with a series of beam splitters, such as dichroic prisms, in order to separate the single light source into the separately colored beams. These embodiments are fully intended to be included in the present invention.

The beams of light 602 from the first light source 601, the second light source 603, and the third light source 605 are preferably directed to illumination optics 607. The illumination optics 607 preferably comprise a series of three individual lenses (not shown individually) to refract and converge the beams of light 602 towards a reflector 609 (discussed further below). Additionally, if desired, the illumination optics 607 may include elements to shape the individual beams of light 602 into more efficient shapes (for example, the shape of the MEMS devices) and also to color correct the beams of light 602.

The beams of light 602 are then preferably directed towards a reflector 609 which preferably directs the beams of light 602 from the first light source 601, the second light source 603, and the third light source 605 onto the first MEMS device 203, the second MEMS device 205, and the third MEMS device 207, respectively, which are all preferably DMDs. The reflector 609 preferably reflects light from each of the first light source 601, the second light source 603, and the third light source 605 to the package 201 and onto the first MEMS device 203, the second MEMS device 205, and the third MEMS device 207, respectively. Preferably, each of the first MEMS device 203, the second MEMS device 205, and the third MEMS device 207 receives a separate color from the first light source 601, the second light source 603, and the third light source 605, and modulates a single color of light. This embodiment, however, is intended to merely be illustrative and not limiting, and any combination of light colors illuminating the individual DMD devices may alternatively be used and remain within the scope of the present invention.

For example, in a package 201 with the first MEMS device 203, the second MEMS device 205, and the third MEMS device 207, the first MEMS device 203 is preferably illuminated with blue light, the second MEMS device 205 is preferably illuminated with red light, and the third MEMS device 207 is preferably illuminated with green light. However, if a package 201 with a fourth MEMS device 501 is used, the additional fourth MEMS device is preferably illuminated with yellow light. Additionally, if a package with only a first MEMS device 203 and a second MEMS device 205 is used, the first MEMS device 203 is preferably illuminated with both red and green colored light, while the second MEMS device 205 is preferably illuminated with both blue and yellow colored light.

The reflector 609 is also preferably used, for example, to separate the path of the beams of light 602 from the path of reflected light 604 from the illuminated MEMS devices. For example, the reflector 609 preferably directs the beams of light 602 from the first light source 601 onto the first MEMS device 203, and also directs reflected light 604 from the first MEMS device 203 in a separate direction and not back towards the first light source 601.

To accomplish this, the reflector 609 is preferably either a single element total internal reflection (TIR) prism or a double element reverse total internal reflection (RTIS) prism. If an RTIS prism is used, the reflector 609 preferably comprises two prisms made of a transparent material with predetermined refraction coefficients to direct the various incoming light beams (from both the light sources and the MEMS devices) in different directions. If a TIR prism is utilized, only a single prism is required, as is known in the art.

However, as one of skill in the art will recognize, there are many different ways of directing the illuminating and reflected light in different directions, and the present application is not intended to be limited to just those means described above. Any and all suitable means for directing the beams of light 602 to the MEMS devices and the reflected light 604 along a different path may alternatively be utilized, and all of these means are fully intended to be included within the scope of the present invention.

Returning to the package with three MEMS devices illustrated in FIG. 6A, once the illumination light is modulated by the first MEMS device 203, the second MEMS device 205, and the third MEMS device 207, the reflected light 604 from each is directed by the reflector 609 to a series of collimator optics 611. The collimator optics 611 preferably collimate and combine the separately colored reflected light 604 into a single image with all of the modulated colors. The collimator optics 611 preferably comprise a series of dichroic filters that allow one or more colors of light to pass without reflection while also reflecting a separate color into alignment with the pass-through colors. In this manner, the separated, modulated colors of reflected light 604 are preferably combined into a single image with preferably the same number of pixels as each of the first MEMS device 203, the second MEMS device 205, and the third MEMS device 207. However, while a series of dichroic filters are preferred, any system of optics, such as an X cube prism, that combines the separate light colors into a single image may alternatively be used.

The combined image 606 from the collimator optics 611 is then preferably sent to a series of projection optics 613. The projection optics 613 preferably comprises a series of lenses designed to focus, expand and converge the combined image 606 into a projection beam (not shown). This projection beam is then preferably projected onto a surface such as a screen 615 which can be viewed by users.

FIG. 6B illustrates another embodiment in which the collimating optics 611, instead of directing the reflected light 604 along the same axis and adding one color of light at a time, preferably directs all of the reflected light 604 to a single prism where all of the reflected light 604 is collimated all at once and directed to the projection optics 613. In this embodiment two of the collimating optics are similar to those described above with respect to FIG. 6A, with one of the collimating optics 611 preferably being rotated so that both collimating optics 611 direct the separated colored light towards each other. The third collimating optic 611 is preferably located between the other two, and is preferably a trichroic prism that can collimate the reflected light 604 from the other two collimatic optics 611 as well as the reflected light 604 from the second MEMS device 205. The combined image 606 is then directed towards the projection optics 613.

By utilizing a single package with multiple MEMS device in this system, the costs of packaging multiple MEMS devices individually can be reduced. Additionally, the manufacturing complications such as transport and testing associated with using multiple packages can be reduced with the use of a single package, thereby making the overall process more efficient.

Although the present invention and its advantages have been described in detail, it should be understood that various changes, substitutions and alterations can be made herein without departing from the spirit and scope of the invention as defined by the appended claims. For example, any number of MEMS devices may be packaged together. Additionally, the present invention may also be utilized in other applications of the packaged MEMS devices, such as their use in a light modulating telecommunication system. Additionally, any light source or combination of light sources may be used to generate the illumination light in a light projection system with the package.

Moreover, the scope of the present application is not intended to be limited to the particular embodiments of the methods described in the specification. As one of ordinary skill in the art will readily appreciate from the disclosure of the present invention, methods presently existing, or later to be developed, that perform substantially the same function or achieve substantially the same result as the corresponding embodiments described herein may be utilized according to the present invention. Accordingly, the appended claims are intended to include within their scope such methods.

What is claimed is:

1. A microelectromechanical system (MEMS) comprising:
a single package; and
a plurality of MEMS devices located within the single package, the plurality of MEMS devices separated from each other by at least one area that contains no MEMS devices.

2. The MEMS of claim 1, wherein the plurality of MEMS devices are located on a single MEMS substrate.

3. The MEMS of claim 1, wherein the plurality of MEMS devices are located on separate MEMS substrates.

4. The MEMS of claim 1, wherein the plurality of MEMS devices consists of three MEMS devices.

5. The MEMS of claim 4, wherein each of the three MEMS devices is situated to reflect a different color of light.

6. The MEMS of claim 1, wherein the plurality of MEMS devices are configured in a portrait configuration.

7. The MEMS of claim 1, wherein the plurality of MEMS devices are configured in a diamond configuration.

8. A digital micromirror device comprising:
a first array of micromirrors;
a second array of micromirrors separated from the first array of micromirrors; and
a package surrounding the first array of micromirrors and the second array of micromirrors, the package comprising a hermetically sealed first surface and a light transmissive second surface to allow light to impinge the first array of micromirrors and the second array of micromirrors.

9. The digital micromirror device of claim 8, further comprising a third array of micromirrors, the third array of micromirrors being separated from the first array of micromirrors and the second array of micromirrors, wherein the package surrounds the third array of micromirrors.

10. The digital micromirror device of claim 8, wherein the first array of micromirrors and the second array of micromirrors are positioned to reflect different colors of light.

11. The digital micromirror device of claim 8, wherein the first array of micromirrors and the second array of micromirrors are arranged in a portrait configuration with respect to each other.

12. The digital micromirror device of claim 8, wherein the first array of micromirrors and the second array of micromirrors are located on a continuous substrate.

13. The digital micromirror device of claim 8, wherein the first array of micromirrors and the second array of micromirrors are located on separate substrates.

14. A projection system comprising:
a light source;
a first reflector positioned to direct light from the light source to a single package, the single package comprising a light-transmissive surface; and
a plurality of micromirror arrays located within the single package, each of the plurality of micromirror arrays being separated from adjoining micromirror arrays by an area containing no micromirrors arrays; and
a second reflector positioned to direct light reflected from the plurality of micromirror arrays to a screen.

15. The projection system of claim 14, wherein each of the plurality of micromirror arrays comprises a first number of pixels and the light reflected from the plurality of micromirror arrays to a screen comprises the first number of pixels.

16. The projection system of claim 14, wherein the plurality of micromirror arrays comprises at least three micromirror arrays.

17. The projection system of claim 14, wherein the light source comprises a plurality of light sources, each light source capable of emitting a different color of light, wherein each micromirror array is positioned to be illuminated by a separate color of light.

18. The projection system of claim 14, wherein the plurality of micromirror arrays are located on a single substrate.

19. The projection system of claim 14, wherein the plurality of micromirror arrays are located on separate substrates.

20. The projection system of claim 14, wherein the plurality of micromirror arrays have edges which do not fall on a line.
